(19) United States
(12) Patent Application Publication
(10) Pub. No.: US 2026/0282256 A1
(43) Pub. Date: Sep. 17, 2026

(54) HEIGHT-ADJUSTABLE HANDLE MECHANISM AND CHASSIS HAVING THE SAME

(71) Applicant: Fulian Precision Electronics (Tianjin) Co., LTD., Tianjin (CN)

(72) Inventor: KE-CHENG LIN, New Taipei (TW)

(21) Appl. No.: 19/210,096

(22) Filed: May 16, 2025

(30) Foreign Application Priority Data
Mar. 17, 2025 (CN) 202510314454.4

(51) Int. Cl. H05K 5/02; H05K 7/14

(52) U.S. Cl. CPC H05K 5/023; H05K 7/1489

(57) ABSTRACT

A height-adjustable handle mechanism includes a base, a rotating shaft, an assembly, and a handle. The base defines a first direction. The rotating shaft is fixed on the base along the first direction and has a helical threaded groove on its outer circumferential surface. The assembly is rotatably sleeved on the rotating shaft and has an inner wall provided with a protrusion that engages the threaded groove. The handle is rigidly connected to the assembly. When an external force rotates the handle about the rotating shaft, the protrusion of the assembly moves along the threaded groove in a spiral path, converting the rotation into an axial displacement of the assembly and the handle along the first direction, thereby adjusting the height of the handle.

### CROSS-REFERENCE TO RELATED APPLICATION(S)

The present application claims the benefit and priority to Chinese Patent Application Serial No. 202510314454.4, filed on Mar. 17, 2025, and the content of which is hereby fully incorporated by reference into the present application.

### FIELD

The subject matter herein generally relates to server chassis, and more particularly, to a height-adjustable handle mechanism for servers and a chassis incorporating the handle mechanism.

### BACKGROUND

A server chassis includes a fixed tray, a carrier that is slidably connected to the tray via rails, and a handle mounted to a front end of the carrier.

In a compacted server chassis, during insertion or removal of the carrier, the handle can easily interfere with the edge of the tray due to slight misalignment or structural deformation. This interference can hinder the movement of the carrier or even cause damage to the related component.

### BRIEF DESCRIPTION OF THE DRAWINGS

Implementations of the present technology will now be described, by way of example only, with reference to the attached figures, wherein:

FIG. 1 is a diagrammatic view of a chassis according to an embodiment of the present disclosure, showing a height-adjustable handle mechanism mounted thereto.

FIG. 2 is a diagrammatic view of the handle mechanism of FIG. 1 in a first state (before the handle is rotated).

FIG. 3 is a diagrammatic view of the handle mechanism of FIG. 1 in a second state (after the handle is rotated).

FIG. 4 is another diagrammatic view of the handle mechanism of FIG. 1, shown from another angle.

FIG. 5 is a partial exploded view of the handle mechanism of FIG. 2.

FIG. 6 is similar to FIG. 5, but shown from a different angle.

FIG. 7 is a diagrammatic view of a movable latch of the handle mechanism of FIG. 2.

FIG. 8 is a diagrammatic view of a button of the handle mechanism of FIG. 2.

FIG. 9 is a diagrammatic view of a rotating shaft of the handle mechanism of FIG. 2.

FIG. 10 is a diagrammatic view of a second plate of the handle mechanism of FIG. 2.

FIG. 11 is a diagrammatic view of a first plate of the handle mechanism of FIG. 2.

FIG. 12 is a diagrammatic view of a base of the handle mechanism of FIG. 2.

### DETAILED DESCRIPTION

It will be appreciated that for simplicity and clarity of illustration, where appropriate, reference numerals have been repeated among the different FIG.s to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

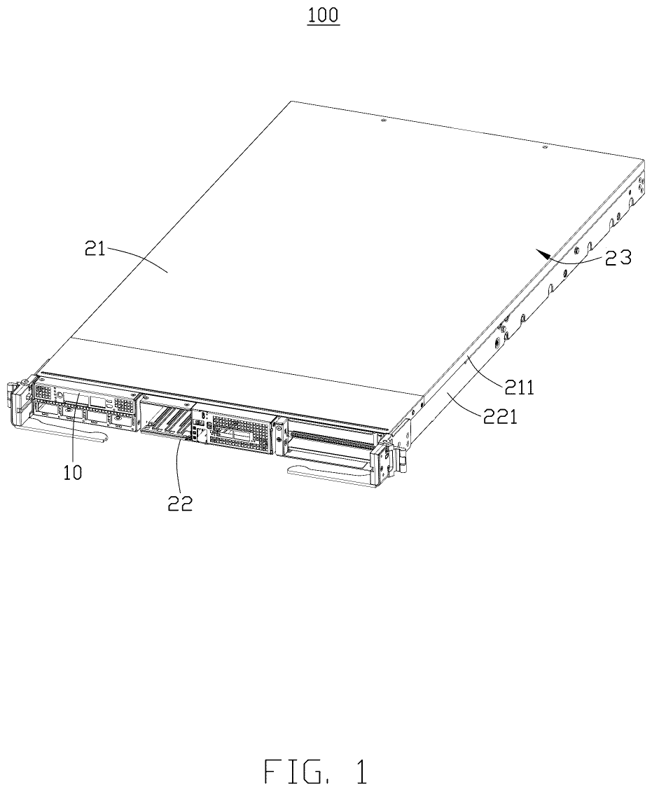

Referring to FIG. 1, a chassis 100 is provided according to an embodiment of the present disclosure. The chassis 100 includes a tray 10, a carrier 20, and a height-adjustable handle mechanism 30 (hereinafter, “handle mechanism 30”). The tray 10 is disposed in the carrier 20 (e.g., slidably received within the carrier 20), and the handle mechanism 30 is mounted to one end of the carrier 20.

The carrier 20 is generally box-shaped, including a top plate 21 and a bottom plate 22. Two top plate connecting portions 211 are formed by bending two sides of the top plate 21 toward the bottom plate 22. Two bottom plate connecting portions 221 are formed by bending two sides of the bottom plate 22 toward the top plate 21. The bottom plate connecting portions 221 are respectively connected to the top plate connecting portions 211, thereby defining an accommodating space 23 between the bottom plate connecting portions 221 and the top plate connecting portions 211. The tray 10 is slidably received in the accommodating space 23 via guide rails, and is used to hold components such as power supplies, heat dissipation units, storage modules, etc. The handle mechanism 30 is connected between the top plate connecting portion 211 and the bottom plate connecting portion 221 of the carrier 20, and is adjustable in height relative to the carrier 20. When the tray 10 needs to be inserted into or pulled out of the chassis, the user can adjust the height of the handle mechanism 30 to maintain a safe clearance between the handle mechanism 30 and the edge of the tray 10. For example, when the tray 10 is fully inserted in the carrier 20, the handle mechanism 30 can be raised close to the bottom surface of the carrier 20 to save space. When operation is needed (such as removing the tray 10), by pressing or rotating the handle mechanism 30, the handle mechanism 30 is lowered to a height that allows the tray 10 to be smoothly pulled out of the carrier 20.

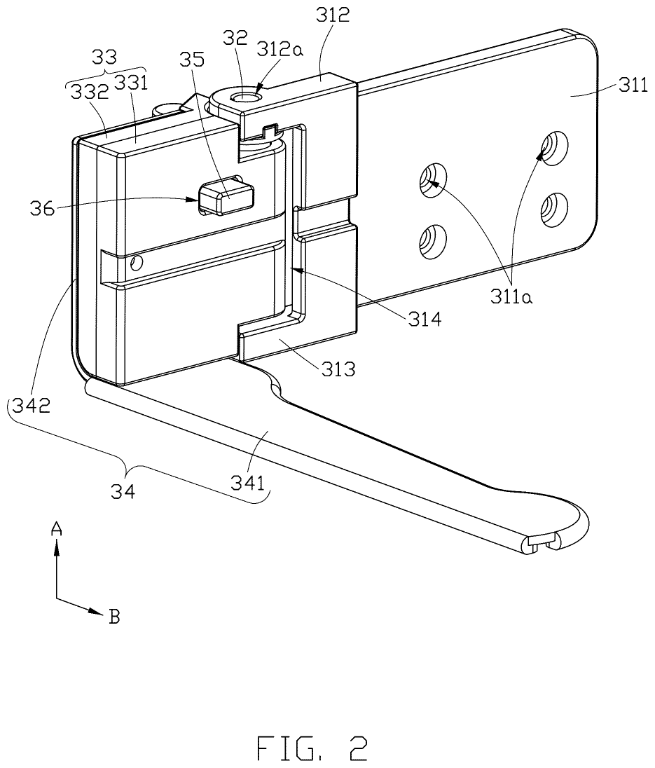

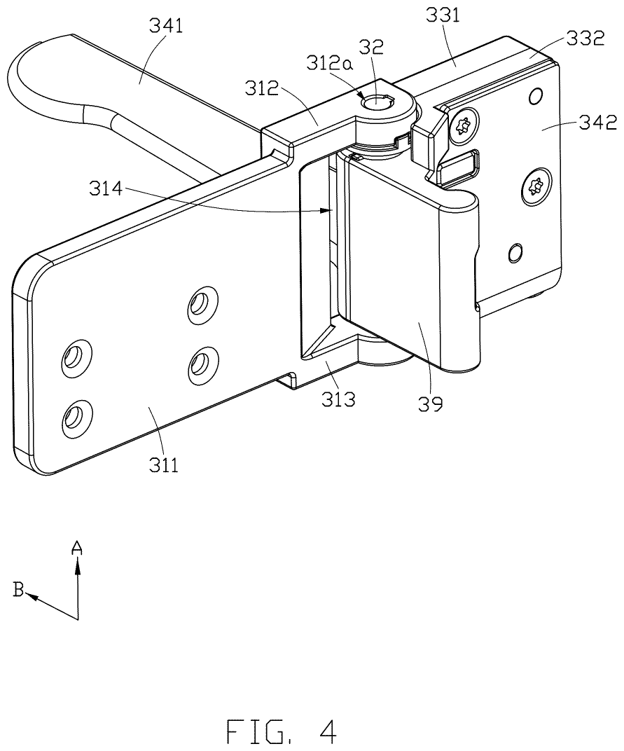

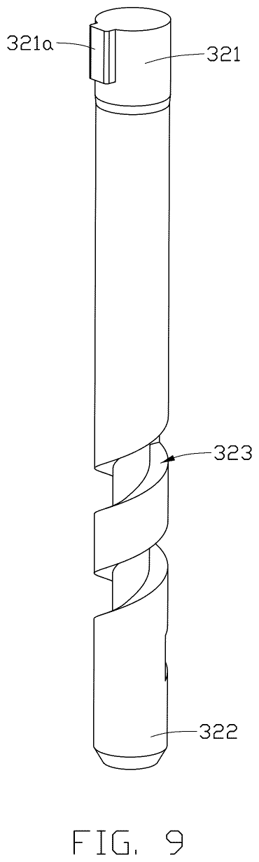

Referring to FIGS. 2, 3, 4, 5 and 6, the handle mechanism 30 includes a base 31, a rotating shaft 32, an assembly 33, and a handle 34. The base 31 defines a first direction A (e.g., a vertical axis). One end of the base 31 can be connected to the carrier 20. The rotating shaft 32 is disposed along the first direction A on the base 31, and an outer circumferential surface of the rotating shaft 32 has a threaded groove 323 (see FIG. 9). The assembly 33 is rotatably sleeved around the rotating shaft 32 and is provided with a protrusion 330. The protrusion 330 is inserted into the threaded groove 323. The handle 34 is connected to the assembly 33. When the handle 34 is rotated under an external force, the protrusion 330 travels along the threaded groove 323 in a helical path, causing the handle 34 and the assembly 33 to move along the first direction A, thereby adjusting the height of the handle 34 relative to the base 31.

Referring to FIG. 2, when it is necessary to remove the tray 10 from the carrier 20, the user rotates the handle 34 of the handle mechanism 30 (for example, counterclockwise), causing the assembly 33 to rotate about the rotating shaft 32. The protrusion 330 of the assembly 33 moves downward along the threaded groove 323 on the rotating shaft 32 due to the guiding function of the threaded groove 323. Accordingly, the handle 34 descends along the first direction A (for instance, the vertical direction). When the handle 34 is adjusted to a predetermined lower position (for example, such that a clearance of about 30-50 mm is maintained from the bottom of the carrier 20), the protrusion 330 is engaged with a positioning structure of the threaded groove 323, thereby holding the handle 34 at a stable height. At this time, the end of the handle 34 and the edge of the tray 10 maintain a safe gap, and the user can pull the tray 10 out smoothly by the handle 34. During the adjustment, the tight engagement between the assembly 33 and the threaded groove 323 ensures that the handle 34 remains stably supported at any selected height, reducing any height deviation under vibration.

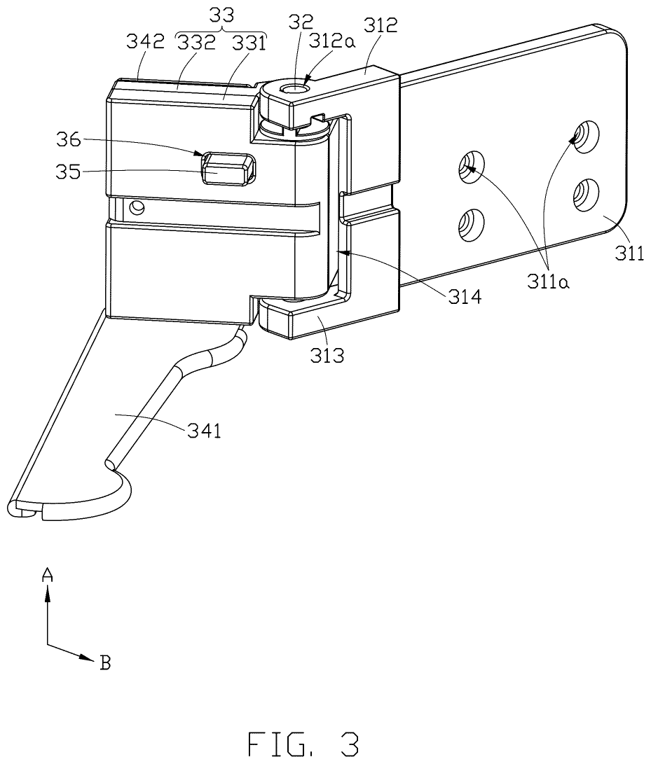

Referring to FIG. 3, after the tray 10 is fully inserted back into the carrier 20, the user rotates the handle 34 in the opposite direction (e.g., clockwise). The protrusion 330 then moves upward along the threaded groove 323, driving the handle 34 back to a raised position near the top of the carrier 20. This adjustment mechanism achieves height locking through a mechanical structure without the need for additional driving components, and the adjustment stroke is linearly related to the thread pitch, ensuring precise operation.

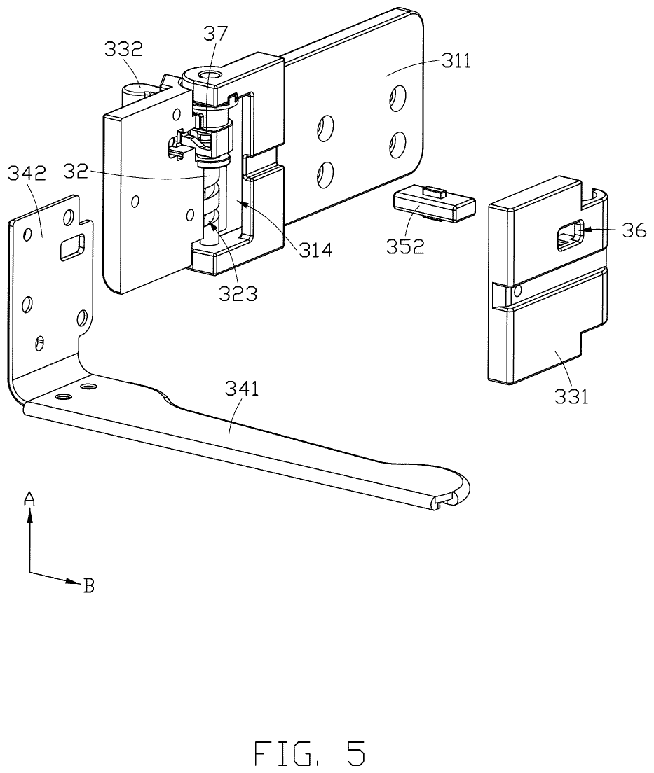

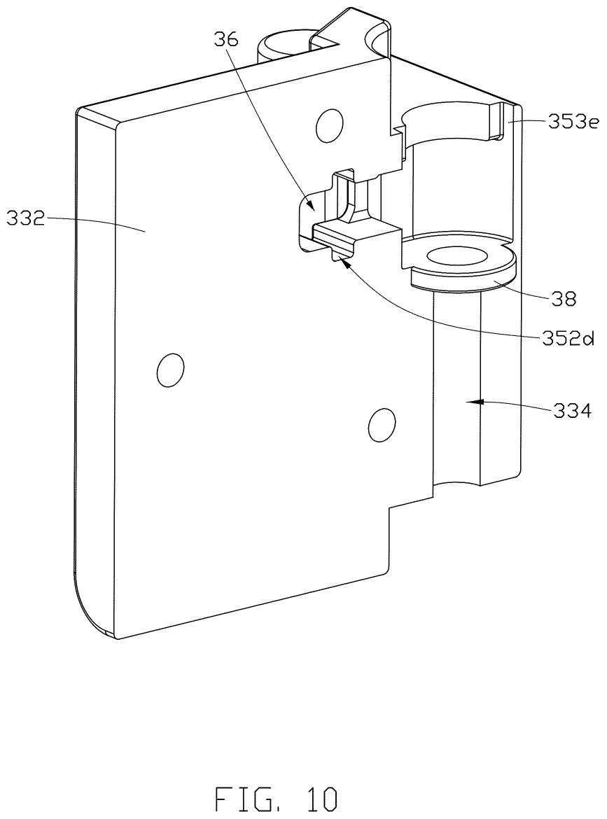

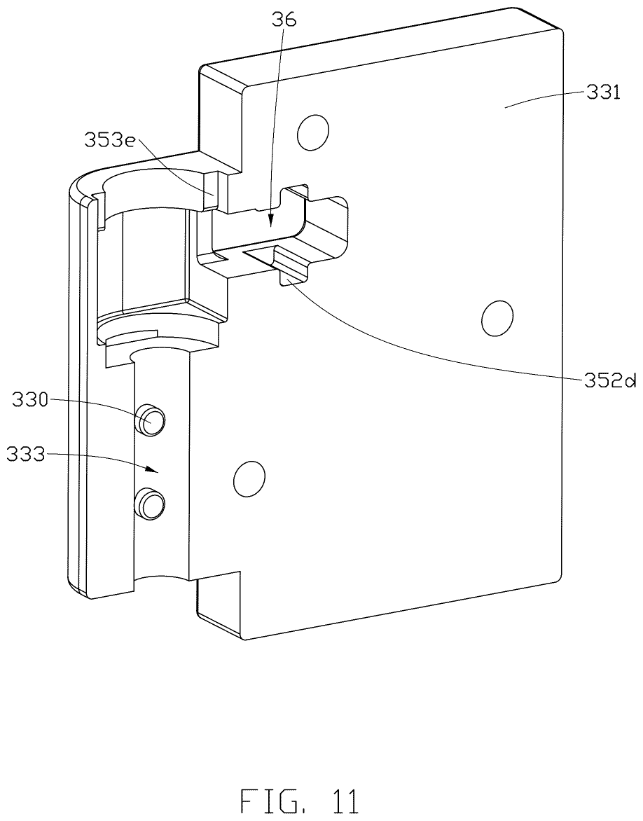

Referring to FIGS. 5, 6, 10, and 11, in this embodiment, the assembly 33 includes a first plate 331 and a second plate 332 connected to first plate 331. The first plate 331 defines a first slot 333 on a side facing the second plate 332, and the second plate 332 defines a second slot 334 on a side facing the first plate 331. The first slot 333 and the second slot 334 communicate with each other to form a shaft hole 335. The rotating shaft 32 extends through the shaft hole 335, and the protrusion 330 is disposed in the first slot 333. In this way, the assembly 33 can rotate relative to the base 31 about the rotating shaft 32. At the same time, due to the engagement of the protrusion 330 with the threaded groove 323, the assembly 33 moves along the first direction A relative to the rotating shaft 32 during rotation, thereby achieving the height-adjustable function.

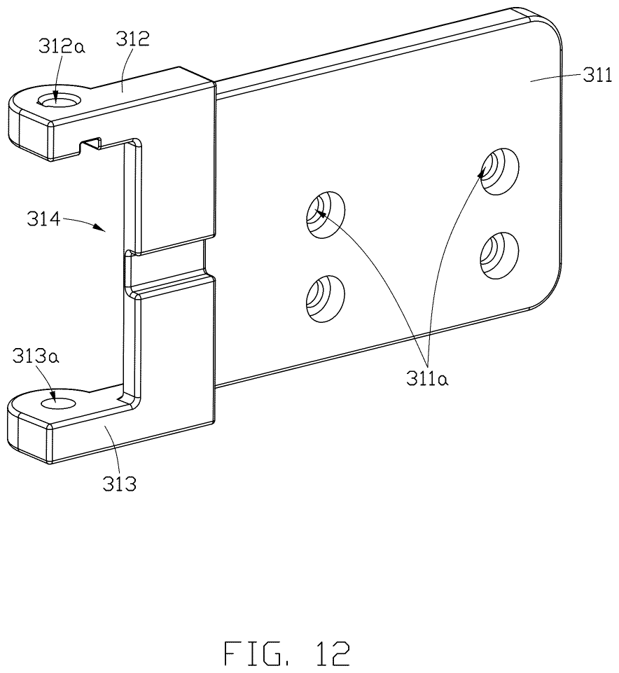

Referring to FIGS. 5, 6, and 12, in this embodiment the base 31 is generally rectangular. The base 31 includes a main body 311, a first extension portion 312, and a second extension portion 313. The first extension portion 312 and the second extension portion 313 protrude from one side of the main body 311 and are spaced apart along the first direction A. The first extension portion 312, the second extension portion 313, and a portion of the main body 311 together define an assembly space 314, and the rotating shaft 32 is disposed in the assembly space 314. The first extension portion 312 defines a first shaft hole 312a and a notch communicating with the first shaft hole 312a (the notch is not shown in the figures). The second extension portion 313 is formed with a second shaft hole 315 (see FIG. 12). The rotating shaft 32 includes a first end 321 and a second end 322. The first end 321 is provided with a locking block 321a protruding outward, and is inserted into the first shaft hole 312a. The second end 322 is inserted into the second shaft hole 315. The locking block 321a is engaged with the notch of the first extension 312, thereby limiting the rotation of the rotating shaft 32 relative to the base 31. The main body 311 defines a number of fixing holes 311a, which cooperates with fasteners (e.g., screw rods) to secure the base 31 to the carrier 20.

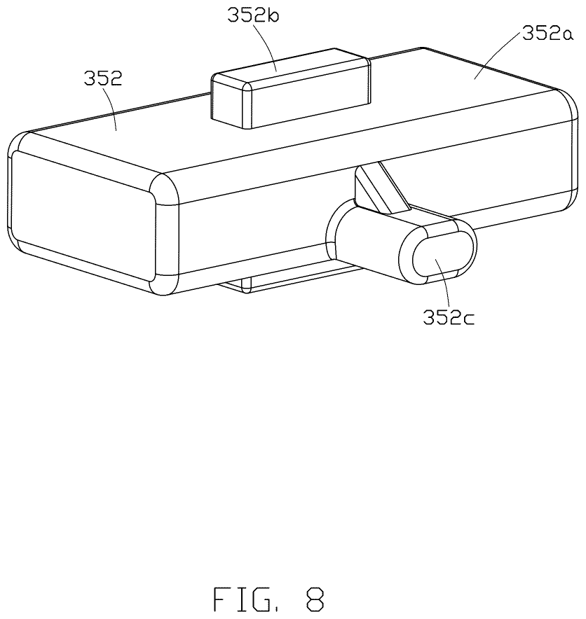

Referring to FIGS. 5, 6, 7, and 8, in this embodiment the handle mechanism 30 further includes a locking assembly 35. The locking assembly 35 includes a movable latch 351 and a button 352. The movable latch 351 includes a sleeve member 353 and a fixing rib 354 protruding from one end of the sleeve member 353. The first extension portion 312 of the base 31 is formed with a locking slot 312c, and the fixing rib 354 is movably insertable into the locking slot 312c. The sleeve member 353 is disposed around (sleeved on) the rotating shaft 32. The sleeve member 353 has an inclined slot 353a, and an extending direction of the inclined slot 353a is oblique (angled) relative to the first direction A. The assembly 33 (i.e., the combined first plate 331 and second plate 332) defines an opening 36. The opening 36 goes through the assembly 33. The opening 36 extends along a second direction B that is perpendicular to the first direction A, and the inclined slot 353a communicates with this opening 36. The button 352 is movably disposed in the opening 36, and a portion of the button 352 extends into the inclined slot 353a.

Referring to FIGS. 2, 3, and 8, in this embodiment, the button 352 includes a button body 352a, a guide block 352b, and a rod body 352c. The guide block 352b is provided on one side of the button body 352a, and the rod body 352c is provided on the opposite side of the button body 352a. The opening 36 (in the assembly 33) extends along the second direction B through both of the first plate 331 and the second plate 332. Both of the first plate 331 and the second plate 332 are formed with aligned guide grooves 352d. The button body 352a is slidably received in the opening 36, and the guide block 352b is slidably received in the guide grooves 352d. Thus, the button body 352a can linearly move along the second direction B but cannot rotate. The rod body 352c is inserted into the inclined slot 353a of the sleeve member 353. When the button body 352a moves along the second direction B (for example, when pushed in a direction away from the first extension portion 312), because the rod body 352c is engaged with the inclined slot 353a and the inclined slot 353a is angled relative to the first direction A, the rod body 352c slides within the inclined slot 353a. As a result, the sleeve member 353 is driven to move upward along the first direction A. In this state, the fixing rib 354 is lifted out of the locking slot 312c (i.e., the locking assembly 35 is unlocked), and the handle mechanism 30 can then be adjusted in height as described above by rotating the handle 34, which causes the protrusion 330 to move along the threaded groove 323 and thereby moves the handle 34 up or down along the first direction A.

After the handle 34 has been adjusted to a desired height, the button 352a can be released or pushed back in the opposite direction (for example, toward the first extension portion 312). The rod body 352c then slides in the inclined slot 353a in the reverse direction, driving the sleeve member 353 downward along the first direction A. The fixing rib 354 is inserted into the locking slot 312c again, thereby locking the handle mechanism 30 at the current height. Thus, during the use of the tray 10, the height of the handle mechanism 30 remains stable and does not change due to external forces or other factors.

Referring to FIGS. 5, 6, and 7, in this embodiment, the locking assembly 35 further includes an elastic member 37, and the assembly 33 further includes a blocking ring 38. The blocking ring 38 is fixedly disposed within the shaft hole 335 of the assembly 33. One end of the elastic member 37 is pressed against an end of the sleeve member 353 that is farthest from the fixing rib 354, and another end of the elastic member 37 is pressed against the blocking ring 38. In the present embodiment, the sleeve member 353 includes a sleeve portion 353b and a housing portion 353c connected to one end of the sleeve portion 353b along the first direction A. The rotating shaft 32 passes through both of the sleeve portion 353b and the housing 353c. The inclined slot 353a is formed at a side wall of the housing 353c. The fixing rib 354 is provided at the end of the sleeve portion 353b that faces away from the housing 353c. The elastic member 37 is a compression spring; one end of the elastic member 37 abuts against the bottom of the housing 353c, and the other end of the elastic member 37 abuts against the blocking ring 38.

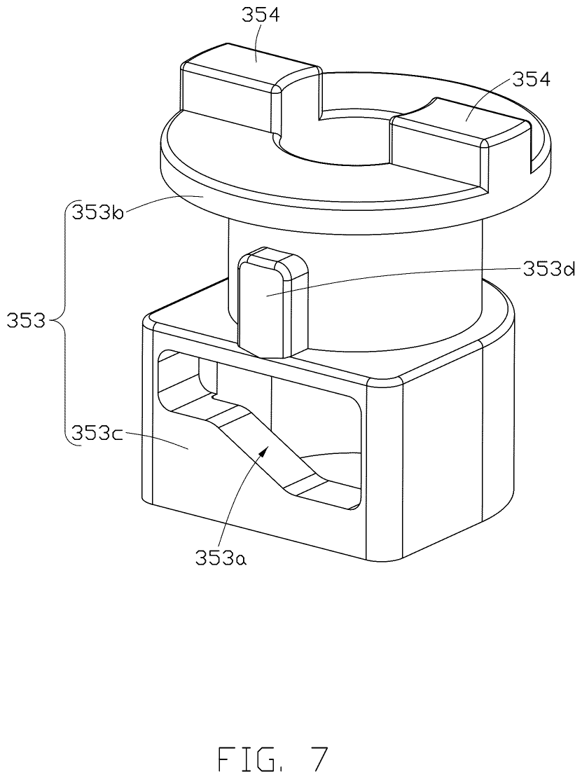

Referring to FIGS. 7, 10, and 11, in this embodiment, an outer side of the sleeve portion 353b of the sleeve member 353 is provided with a limiting block 353d that extends along the first direction A. The assembly 33 is further formed with a limiting hole 353e that extends along the first direction A and communicates with the shaft hole 335. The limiting block 353d is inserted into the limiting hole 353e. In this way, the sleeve member 353 is guided by the cooperation of the limiting block 353d and the limiting hole 353e to move only along the first direction A (up and down), and is prevented from rotating relative to the assembly 33 when the button 352 is pressed.

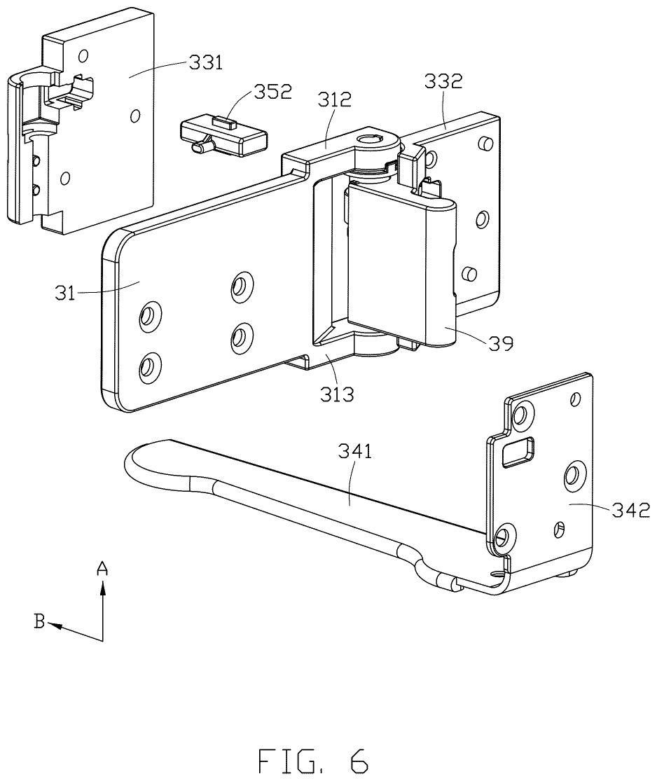

Referring to FIGS. 3 and 6, in this embodiment, the handle mechanism 30 further includes a limiting portion 39. The limiting portion 39 is connected to an end of the assembly 33, and is configured to abut against the base 31 to define the rotational range of the handle 34. The handle 34 includes a grip portion 341 and a bent portion 342 connected to the grip portion 341, with the bent portion 342 being connected to the assembly 33. The bent portion 342 is attached to the second plate 332 by a fastener (for example, a screw rod). The limiting portion 39 acts as a stop such that when the handle 34 is rotated to a limiting position, the limiting portion 39 is in contact with the base 31, thereby preventing further rotation of the handle 34 and thus protecting the handle 34 from over-rotation.

The embodiments shown and described above are only examples. Many details are often found in the art such as the other features of the handle mechanism 30. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. A height-adjustable handle mechanism, comprising:
a base defining a first direction;
a rotating shaft disposed on the base and extending along the first direction, the rotating shaft having an outer circumferential surface defining a threaded groove;
an assembly rotatably sleeved around the rotating shaft, the assembly comprising a protrusion engaged with the threaded groove, and
a handle connected to the assembly;
wherein when the handle is rotated under an external force, the protrusion helically moves along the threaded groove, thereby driving the handle to move along the first direction to adjust a height of the handle.

2. The height-adjustable handle mechanism of claim 1, wherein the assembly comprises a first plate and a second plate connected to the first plate, the first plate defines a first slot on a side facing the second plate, the second plate defines a second slot on a side facing the first plate, the first slot and the second slot communicate with each other to form a shaft hole, the rotating shaft is disposed in the shaft hole, and the protrusion is disposed in the first slot.

3. The height-adjustable handle mechanism of claim 2, wherein the base comprises a main body, a first extension portion, and a second extension portion, the first extension portion and the second extension portion protrude from one side of the main body, the first extension portion and the second extension portion is spaced from each other along the first direction, the first extension portion, the second extension portion, and a part of the main body together define an assembly space, and the rotating shaft is disposed in the assembly space.

4. The height-adjustable handle mechanism of claim 3, wherein the first extension portion defines a first shaft hole and a notch communicating with the first shaft hole, the second extension portion defines a second shaft hole, the rotating shaft comprises a first end and a second end, the first end is provided with a locking block, the first end is inserted into the first shaft hole, the locking block is inserted into the notch, and the second end is inserted into the second shaft hole.

5. The height-adjustable handle mechanism of claim 3, further comprising a locking assembly, wherein the locking assembly comprises a movable latch and a button; the movable latch comprises a sleeve member and a fixing rib protruding from one end of the sleeve member; the first extension portion defines a locking slot, the fixing rib is movably insertable into the locking slot; the sleeve member is sleeved on the rotating shaft; the sleeve member has an inclined slot, an extending direction of the inclined slot is inclined relative to the first direction; the assembly defines an opening extending along a second direction, the inclined slot communicating with the opening, the second direction is perpendicular to the first direction; the button is movably disposed in the opening, and a portion of the button is inserted into the inclined slot.

6. The height-adjustable handle mechanism of claim 5, wherein the locking assembly further comprises an elastic member, the assembly further comprises a blocking ring fixed in the shaft hole, one end of the elastic member abuts against an end of the sleeve member away from the fixing rib, and another end of the elastic member abuts against the blocking ring.

7. The height-adjustable handle mechanism of claim 5, wherein an outer side of the sleeve member protrudes to form a limiting block, the assembly defines a limiting hole extending along the first direction and communicating with the shaft hole, and the limiting block is inserted into the limiting hole.

8. The height-adjustable handle mechanism of claim 1, further comprising a limiting portion connected to an end of the assembly, wherein the limiting portion is configured to abut against the base.

9. The height-adjustable handle mechanism of claim 1, wherein the handle comprises a grip portion and a bent portion connecting the grip portion, and the bent portion is connected to the assembly.

10. A chassis, comprising:
a tray;
a carrier; and
a height-adjustable handle mechanism comprising:
a base defining a first direction;
a rotating shaft disposed on the base and extending along the first direction, the rotating shaft having an outer circumferential surface defining a threaded groove;
an assembly rotatably sleeved around the rotating shaft, the assembly comprising a protrusion engaged with the threaded groove, and
a handle connected to the assembly;
wherein when the handle is rotated under an external force, the protrusion helically moves along the threaded groove, thereby driving the handle to move along the first direction to adjust a height of the handle;
the tray is slidably disposed in the carrier, and the height-adjustable handle mechanism is mounted at one end of the carrier.

11. The chassis of claim 10, wherein the assembly comprises a first plate and a second plate connected to the first plate, the first plate defines a first slot on a side facing the second plate, the second plate defines a second slot on a side facing the first plate, the first slot and the second slot communicate with each other to form a shaft hole, the rotating shaft is disposed in the shaft hole, and the protrusion is disposed in the first slot.

12. The chassis of claim 11, wherein the base comprises a main body, a first extension portion, and a second extension portion, the first extension portion and the second extension portion protrude from one side of the main body, the first extension portion and the second extension portion is spaced from each other along the first direction, the first extension portion, the second extension portion, and a part of the main body together define an assembly space, and the rotating shaft is disposed in the assembly space.

13. The chassis of claim 12, wherein the first extension portion defines a first shaft hole and a notch communicating with the first shaft hole, the second extension portion defines a second shaft hole, the rotating shaft comprises a first end and a second end, the first end is provided with a locking block, the first end is inserted into the first shaft hole, the locking block is inserted into the notch, and the second end is inserted into the second shaft hole.

14. The chassis of claim 12, wherein height-adjustable handle mechanism the further comprises a locking assembly, wherein the locking assembly comprises a movable latch and a button; the movable latch comprises a sleeve member and a fixing rib protruding from one end of the sleeve member; the first extension portion defines a locking slot, the fixing rib is movably insertable into the locking slot; the sleeve member is sleeved on the rotating shaft; the sleeve member has an inclined slot, an extending direction of the inclined slot is inclined relative to the first direction; the assembly defines an opening extending along a second direction, the inclined slot communicating with the opening, the second direction is perpendicular to the first direction; the button is movably disposed in the opening, and a portion of the button is inserted into the inclined slot.

15. The chassis of claim 14, wherein the locking assembly further comprises an elastic member, the assembly further comprises a blocking ring fixed in the shaft hole, one end of the elastic member abuts against an end of the sleeve member away from the fixing rib, and another end of the elastic member abuts against the blocking ring.

16. The chassis of claim 15, wherein an outer side of the sleeve member protrudes to form a limiting block, the assembly defines a limiting hole extending along the first direction and communicating with the shaft hole, and the limiting block is inserted into the limiting hole.

17. The chassis of claim 1, wherein the height-adjustable handle mechanism comprises a limiting portion connected to an end of the assembly, wherein the limiting portion is configured to abut against the base.

18. The chassis of claim 1, wherein the handle comprises a grip portion and a bent portion connecting the grip portion, and the bent portion is connected to the assembly.
